(19) United States
(12) Patent Application Publication
(10) Pub. No.: US 2008/0111633 A1
(43) Pub. Date: May 15, 2008

(54) Systems and Arrangements for Controlling Phase Locked Loop

(75) Inventors: Hayden C. Cranford, Cary, NC (US); Marcel A. Kossel, Reichenburg (CH); Thomas H. Toifl, Zurich (CH)

Correspondence Address: IBM COPORATION (RTP);C/O SCHUBERT OSTERRIEDER & NICKELSON PLLC, 6013 CANNON MOUNTAIN DRIVE, S14, AUSTIN, TX, 78749, US

(73) Assignee: International Business Machines Corporation, Armonk, NY (US)

(21) Appl. No.: 11/558,127

(22) Filed: Nov. 9, 2006

(51) Int. Cl. H03L 7/089

(52) U.S. Cl. 331/10

(57) ABSTRACT

A multi-Gigahertz, low jitter phase locked loop (PLL) with adjustable gain is disclosed. In one embodiment, properties of a f_{VCO} signal of a PLL can be acquired. Properties can include the occurrences of different types of jitter on the f_{VCO} signal and the lock status of the PLL. A gain control module can control at least a portion of the PLL based on an analysis of the acquired properties. For example, when the loop is locked or when there is loop filter leakage, the gain of a charge pump in the PLL can be reduced. When a charge pump mismatch is detected based on the acquired properties, additional control signals can be provided to the charge pump to correct the mismatch.

### FIELD OF INVENTION

The present disclosure pertains to the field of clock generating circuits and further to the field of phase locked loops.

### BACKGROUND

Generally, each new generation of electronic equipment processes data at higher speeds and can communicate at higher speeds. Accordingly, clocks that run such electronic devices are required to operate at higher speeds in each new generation of devices. As clock speeds and data rates increase into the multi Gigahertz/Gigabit per second range, many design challenges arise. For example, jitter becomes a significant factor in clock signals because it can cause serious degradation in system performance. Jitter can be defined as a “shaky” pulse or a deviation, variation, or displacement of some portion of a clock pulse from a desired shape. This deviation often includes amplitude variations, phase timing width variations and/or just a pulse or a period frequency that becomes displaced from the desired shape.

Generally, clock signals are utilized in data processing systems and communication systems to synchronize circuit operation. One application for such clock signals is in clock and data recovery (CDR) systems. CDR systems can provide system wide synchronization of circuits where such circuits may operate in the Gigahertz range while being separated by a relatively large distance. It is a significant technological challenge to synchronize the timing of the receiver with the incoming data waveform at such high frequencies. Other clock signal applications include various radio frequency transmitters and receivers, navigation equipment and other communications equipment.

To ensure synchronization a core clock or system clock can be distributed to numerous phase locked loops, (PLL)s in an integrated circuit and the PLLs can synchronize with the system clock to generate synchronized clock signals locally such that system wide synchronization can be achieved. At higher clock frequencies, PLLs are commonly a source of jitter. PLLs generally, accept a system reference clock signal on an input and provide a robust clock signal that is in phase with the reference signal on their output. In clock generating applications PLLs typically work as frequency multipliers whereas the PLL output signal corresponds to an integer or fractional multiple of the reference frequency. Such a PLL can control an internal oscillator based on comparing the divided output signal of the PLL to the incoming reference signal. A PLL can maintain a constant phase angle on its output relative to the reference signal on its input. The output of the PLL can be utilized to drive other circuits such as communication circuits, data processing circuits, clock and data recovery (CDR) circuits, coherent carrier tracking circuits and threshold extension circuits, bit synchronization circuits, and symbol synchronization circuits.

As mentioned above, PLL jitter becomes a significant problem at higher clock frequencies such as clock frequencies in the Gigahertz range. The jitter transfer characteristic from the reference frequency input to the output of the PLL represents a low pass filter whereas the jitter transfer characteristic from the voltage controlled oscillator (VCO) in the PLL to the output of the PLL represents a high pass filter. This configuration has two significant implications when the reference signal and the VCO are considered as being the main contributors to jitter in the PLL's output signal. First, if the reference signal is the main jitter contributor, a VCO with a high quality factor (e.g. LC tank VCO) can be used together with a narrow loop bandwidth to generate a PLL output signal with low jitter.

Second, if the VCO is the main source of jitter and the reference signal is “substantially” jitter free (or has low jitter), a wide loop bandwidth can be chosen to generate a low jitter PLL output signal. If the reference signal is not sufficiently clean of jitter, a cascade of two PLLs is often utilized to first “clean up” the reference signal. The first PLL stage can utilize a high quality factor VCO with a narrow band loop filter and feed the “cleaned up” clock signal to a second stage PLL. The second stage PLL can have a wide loop bandwidth to reduce the jitter contribution of the PLL and particularly the jitter caused by the VCO in the second stage PLL such that the output signal of cascaded PLLs is very low in jitter. It is also desirable to utilize a very high frequency signal in the frequency feedback loop to suppress the jitter because a feedback divider with a small value can assist in suppressing jitter.

However, such a high frequency feedback loop signal typically prohibits using a conventional sequential phase frequency detector (PFD) with an internal feedback loop in the PLL circuit. The PFD is typically the input stage of a PLL and traditional PFDs cannot switch fast enough to accommodate this high frequency input. When operating in the multi-Gigahertz range PLL designs can have many problems including control problems in a “dead zone” when the PLL is close to “phase-lock.” The PLL can be so close to phase lock that the feedback frequency does not have the gain resolution required to achieve a lock and the output frequency will overshoot and undershoot the desired frequency during the locking process for a number of cycles. One problem with the above mentioned feed forward PFDs is that the gain of such a PFD can be relatively high, or higher than traditional PFDs. This higher gain is desirable when the PLL is attempting to achieve a phase lock, because a lock can be achieved quicker, but after a phase lock is established this higher gain can lead to other instabilities. For example, noise on the input of the PFD can be amplified by a PFD with a higher gain leading to such PLL instability.

Accordingly, specific levels of gain are desirable for specific stages or modes of operation and specific components of a PLL during the specific modes of operation and other levels of gain are undesirable for specific stages of the PLL during other modes of PLL operation. Accordingly, a reliable high speed PLL with adjustable gain properties and low jitter would be very useful.

### SUMMARY OF THE INVENTION

The problems identified above are in large part addressed by the systems, methods and media disclosed herein to provide a high speed, low jitter phase locked loop (PLL) with adjustable loop gain features. Thus, a multi-Gigahertz PLL, having self-adjusting gain features responsive to monitored operational phenomena or PLL properties is disclosed. In one embodiment, properties of a f_{VCO} signal of a PLL can be acquired. These properties can include the number of occurrences or frequency and magnitude of different types of jitter on f_{VCO} and, on the lock status of the loop. A gain control module can provide variable gain control of at least a portion of the PLL loop based on an analysis of the acquired properties. For example, when the loop is locked or when loop filter leakage is detected, the loop gain characteristics of the PLL can be adjusted via the charge pump where it has been determined that control of the loop gain is easier to establish than with other loop components such as the oscillator, or the phase frequency detector. Such a location reduces the number of controller circuits. When the acquired properties indicate that a charge pump mismatch is occurring or has occurred, control signals can be provided to the charge pump to correct the mismatch.

In one embodiment, a method for controlling a PLL includes receiving a reference signal and a PLL feedback signal and acquiring properties of the PLL signal. A PFD and a gain controller can generate a control signal and a loop gain signal based on the acquired properties, where the control signal can be on separate conductor from the gain signal. The control signal can be fed to a first input of an oscillator controller, such as a first bank of current sources of a charge pump and the gain signal can be fed to a second input of the oscillator controller to set the current flow of the charge pump.

The method can also include applying a first gain signal with a predetermined amount of gain to the oscillator controller or charge pump in response to determining that the phase locked loop is out of lock, and applying a second gain signal with a second predetermined amount of gain to the oscillator controller or charge pump in response to determining that the phase locked loop is locked. In addition, the gain signal can be selectively provided to one or more current sources or current sinks in the oscillator controller or charge pump. The gain can be provided based on acquiring statistics on jitter of the phased locked loop feedback signal. To acquire jitter statistics the phase locked loop feedback signal and the reference signal can be delayed by predetermined intervals and a counter can count the occurrences of when the feedback signal is early and when the feedback signal is late during a peak-to-peak interval. The counted occurrences can be stored over a predetermined number of cycles to derive statistics on the jitter of the PLL. Based on the jitter statistics a control signal with gain can be generated and provided to a charge pump to adjust the loop gain to increase the stability of the PLL. One way to increase the stability of the PLL and reduce unwanted jitter in the locked state of the PLL, is to lower the gain provided by a phase frequency detector and transfer this gain to components such as a current pump that controls the frequency of the oscillator of the PLL. This can be accomplished responsive to the acquired jitter statistics during a locked condition.

In another embodiment, a gain control apparatus for a phase locked loop is disclosed. The gain control apparatus can include a first delay module for delaying a reference signal, a second delay module for delaying a loop feedback signal, wherein the first delay module provides a different delay time such that the loop feedback signal has a different delay than the delayed reference signal. The apparatus can also include a jitter counter, to count occurrences of an edge of the delayed reference signal occurring at a different time than an edge of the delayed loop feedback signal, and an evaluation logic module to evaluate the count of occurrences and to provide a gain control output in response to the evaluated count. The count can be evaluated after a cycle counter counts a predetermined number of cycles. A third delay module and a second counter can also be included in the gain module. The delay module can delay the reference signal more than the feedback signal and the jitter counter to acquire statistics about late arrivals of a rising edge of the feedback signal.

In yet another embodiment, a phase locked loop system is disclosed. The system can include a phase frequency detector to receive a reference signal and a loop feedback signal, and to provide one of an increase or a decrease output signal to an oscillator controller. The system can also include a gain control module to receive the reference signal and the loop filter signal and to acquire data related to the loop filter signal and the reference signal and provide an output signal to control gain in the PLL responsive to the data. A charge pump with an adjustable gain can receive the output of the gain control module and provide an oscillator control signal on its output based on the output signal of the gain control unit. The system can also include an oscillator to receive the output of the charge pump via a loop filter that performs a current-to-voltage conversion, such that the oscillator can change an oscillation frequency responsive to the output of the charge pump. The gain control module can include a counter to acquire jitter data or to count the occurrences of jitter in a time period in the feedback loop. The disclosed PLL can receive a “jittery” reference signal on a first PLL stage and provide an output signal on a second PLL stage having a frequency above one and a half Gigahertz with minimal jitter.

### BRIEF DESCRIPTION OF THE DRAWINGS

Aspects of the invention will become apparent upon reading the following detailed description and upon reference to the accompanying drawings in which, like references may indicate similar elements:

FIG. 1 depicts a block diagram of a two-stage phase locked loop;

FIG. 2 illustrates a block diagram of a gain control module in a phase locked loop;

FIG. 3A depicts a more detailed embodiment of a gain control unit;

FIG. 3B illustrates a delay module suitable for use by a gain control unit;

FIG. 4 shows a timing/logic diagram of a gain controller where τⱼᵢₜₜₑᵣ+τ_{D1}<T_{ref} and τ_{D1}>τⱼᵢₜₜₑᵣ>0 where the jitter is early;

FIG. 5 depicts another timing/logic diagram of a gain control where τⱼᵢₜₜₑᵣ+τ_{D2}<T_{ref} and 0<τⱼᵢₜₜₑᵣ<τ_{D2} where jitter is late;

FIG. 6 illustrates another timing/logic diagram of a gain control module where τⱼᵢₜₜₑᵣ+τ_{D1}<T_{ref} and τ_{D1}<τⱼᵢₜₜₑᵣ;

FIG. 7 shows another timing/logic diagram of a gain control module where τⱼᵢₜₜₑᵣ+τ_{D2}<T_{ref} and τ_{D2}<τⱼᵢₜₜₑᵣ;

FIG. 8 depicts another timing/logic diagram of a gain control module where τⱼᵢₜₜₑᵣ+τ_{D1}>T_{ref};

FIG. 9 illustrates another timing/logic diagram of a gain control module where τⱼᵢₜₜₑᵣ+τ_{D2}>T_{ref}; and

FIG. 10 is a flow diagram of a method of controlling gain in a phase locked loop.

### DETAILED DESCRIPTION OF EMBODIMENTS

The following is a detailed description of embodiments of the disclosure depicted in the accompanying drawings. The embodiments are in such detail as to clearly communicate the disclosure. However, the amount of detail offered is not intended to limit the anticipated variations of embodiments; on the contrary, the intention is to cover all modifications, equivalents, and alternatives falling within the spirit and scope of the present disclosure as defined by the appended claims. The descriptions below are designed to make such embodiments obvious to a person of ordinary skill in the art.

While specific embodiments will be described below with reference to particular configurations of hardware and/or software, those of skill in the art will realize that embodiments of the present invention may advantageously be implemented with other equivalent hardware and/or software systems. Aspects of the disclosure described herein may be stored or distributed on computer-readable media, including magnetic and optically readable and removable computer disks, as well as distributed electronically over the Internet or over other networks, including wireless networks. Data structures and transmission of data (including wireless transmission) particular to aspects of the disclosure are also encompassed within the scope of the disclosure.

In accordance with the present disclosure, loop gain adjustment systems and methods that are suitable for use in a phase locked loop (PLL) circuit are disclosed. The system and method can measure the jitter generation caused by loop filter leakage or other jitter generating effects such as a charge pump mismatch, and adjust the PLL's loop gain to compensate for these non-idealities. The measurement of the jitter generation can be based on an evaluation of clock edge statistics in predefined timing intervals at the input of a phase frequency detector (PFD) of the PLL. A look up table can be utilized to determine what gain control signals should be provided in the PLL, based on the detected jitter measurements/clock edge statistics.

Accordingly, a multi-Gigahertz, low jitter, phase locked loop (PLL) with adjustable gain is described herein. To achieve such a configuration, properties of a f_{VCO} signal of a PLL can be acquired by a gain control module. Properties can include logged occurrences of different types of jitter on f_{VCO} and the lock status of the loop. The gain control module can control at least a portion of the loop based on an analysis of the acquired properties. For example, when jitter generating non-idealities such as loop filter leakage occur in the PLL loop, these non-idealities may degrade the PLL's phase noise or jitter performance. When such a phenomena is detected, the gain of the charge pump in the PLL can be adjusted by the gain control module to counteract the influence of these non-idealities on the loop dynamics. When a charge pump mismatch is detected based on the acquired jitter properties, additional control signals can be provided to the charge pump to correct the charge pump mismatch.

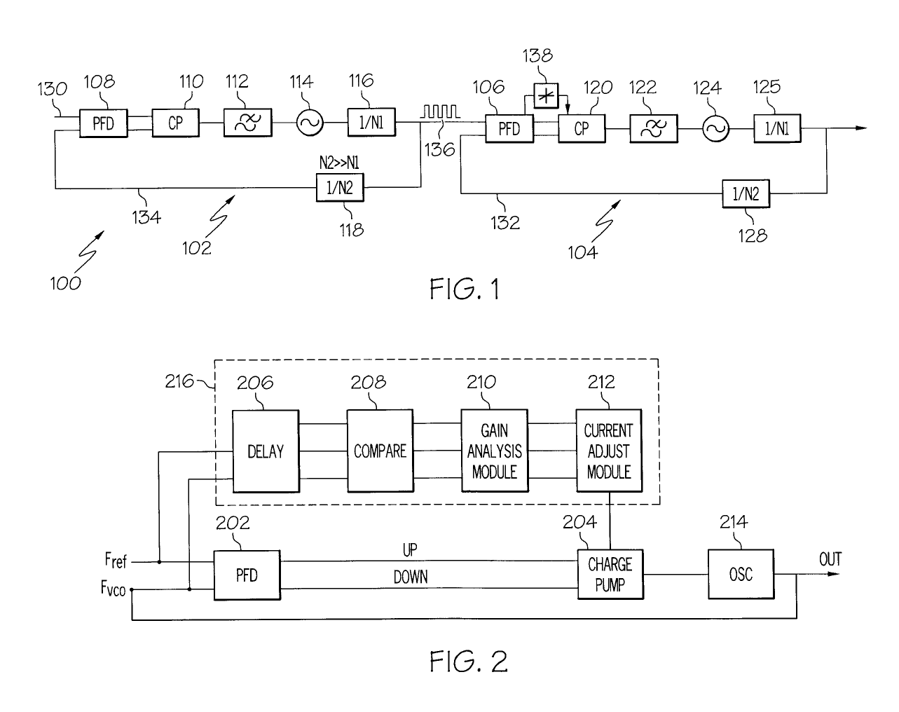

Referring to FIG. 1 a two stage PLL is illustrated. In one embodiment, the first stage 102 of the PLL is similar to the second stage 104 of the PLL with the exception that the second stage 104 can utilize a feed forward phase frequency detector (FFPFD) 106. Further, the second stage 104 can utilize a gain analysis/control module 138 to forward and control a gain signal to a charge pump 120 in the loop. The FFPFD 106 and the second stage 102 can operate at frequencies that are magnitudes higher than traditional PFDs and traditional PLLs due to the PLLs feed forward design and the gain control features of the PLL. Further, the PLL can have improved loop stability due to the FFPFD 106 and the features of the gain analysis/control module 138.

The first phase locked loop 102 can include a phase frequency detector (PFD) 108, a charge pump 110, a small band width filter 112, a high quality factor (high-Q) local oscillator 114, and a 1/N1 frequency divider 116. In operation, a low frequency reference signal can be provided to the input of the PFD 108, and based on the detected phase difference; the PFD 108 can drive the charge pump 110. The output signal of the charge pump can be fed to the filter 112 and the filtered signal can be utilized to control the output signal of the local oscillator. The output signal of the local oscillator can be provided to frequency divider 116. The output signal can again be divided by the 1/N2 divider in the feedback loop 134 and this feedback signal can be returned to the PFD 108 as feedback such that the output of the first stage 102 can provide a precise, robust clock signal to the second stage 104. The local oscillator 114 can also include a small inductance, and a high frequency oscillator with a high Q value, which allows the loop bandwidth of PLL 102 to be small and the first stage 102 can perform a “clean up” function on a jittery reference signal 130. It has been determined that the jitter transfer characteristic from the reference frequency input 130 to the output signal 136 of the first PLL 102 provides a low pass filter that can reduce any jitter present on the reference frequency signal 130. Thus, the smaller the loop bandwidth in the first stage 102 of the PLL the better the suppression of reference signal jitter. However, this same loop filter configuration can act as a high pass filter when the jitter transfer characteristic from the VCO 114 to the PLL output 136 is considered and hence a high quality factor VCO 114 is desired to keep the jitter caused by the VCO 114 at the PLL output signal 136 as small as possible.

The second phase locked loop 104 can include a feed forward phase frequency detector (FFPFD) 106, a gain control module 138, a charge pump 120, a filter with a high band width 122, a local oscillator 124, and a (1/N1) frequency divider 125. In operation, the high frequency reference signal 136 from the output of the first stage 102 can be fed to the input of the FFPFD 106 and based on the phase difference detection between the feedback loop signal 132 and the high frequency reference signal 136, the FFPFD 106 can drive the charge pump 120, and the gain controller 138 which will correct the oscillator frequency if there is a detected phase difference at the input of the FFPFD 106. The output signal of the charge pump 120 can be fed to the filter 122 and the filtered signal can control the operating frequency of the local oscillator 124 to provide a signal to the divider 125 before the signal is output as a synchronized clock signal. The clock signal can be divided by the 1/N2 divider 128 and provided as feedback to FFPFD 106 such that the output of the second stage PLL 104 can provide a synchronized, stable “jitter free” clock signal to operational circuits.

As stated above, in one embodiment, the PFD 108 in the first stage 102 can be a conventional PFD that will accept a relatively low reference signal frequency on its input. However, the first stage 102 may produce an output reference frequency of greater than five (5) Gigahertz. The second stage PFD 106 can accept this relatively high frequency output signal of the first stage 102 and can process a relatively high frequency control loop signal because the second stage 104 utilizes feed forward control on the FFPFD 106 and the feed forward features of the gain analysis/control module 138. The FFPFD 106 of the second stage 104 can detect a difference in phase in real time between the input from the first stage 102 and the feedback signal on line 132, and provide an accurate output signal representing the difference in phase between these two signals when operating at this high frequency. Likewise, the gain analysis/control module 138 of the second stage 104 can detect a difference in phase between the signals over a predetermined period of time and make a statistical determination of where gain should be applied and how much gain should be applied to components of the PLL 104. This can ensure that the following two objectives are met: (a) a high loop gain is provided when the PLL is in a transient condition, speeding the acquisition time of the lock which is important during frequency changes; and (b) a small loop gain adjustments can be made when the PLL is in the locked state to make it less prone to jitter generating non-idealities from loop filter leakage and charge pump mismatches. Both objectives help improve the PLL performance in terms of faster acquisition time and lower jitter generation.

Thus, in operation, the FFPFD 106 can measure the phase difference between the reference signal 136 provided by the first stage 102 and the divided VCO signal 132 on the feedback loop 132 and provide a pulse having a duration that is commensurate with the phase difference of signals 132 and 136. Similarly the gain analysis module 138 can take more of a long term statistical approach to loop performance/stability and correct the loop operation accordingly. The reference signal 130 on the input of the PLL 100 is often a “global” system clock that is distributed to the majority of systems that are co-located with the PLL 100 on the same chip or integrated circuit. The input of the first stage 102 can be impedance matched to the wiring of the clock distribution network such that the first stage 102 does not significantly load or alter the system reference signal. The low frequency nature of the first stage 102 is provided such that the first stage provides a low propagation loss to the global clock distribution network. Generally, first stage PLL 102 will not substantially load the system reference clock and the first stage can “clean up” jitter and other noise often present on the system reference clock signal 130. Ever present insertion loss of the PLL's input stage measured utilizing reflection scattering parameter “S11” and more particularly propagation loss measured by the transmission scattering parameter “S21” of the clock distribution wiring requires the system clock signal to be routed as a “low” frequency signal, particularly when the clock signal must travel over larger distances (i.e. several millimeters or centimeters). High frequency system clocks are not utilized because system power consumption would become cost prohibitive.

As stated above, the reference signal 130 will typically be a system clock with a “global” distribution on the chip because of the low insertion loss owing to its low frequency nature. However, the oscillators 114 and 124 can have much different requirements. While VCO 114 can have a high Q and hence be a narrow band oscillator to perform the clean up function of the reference frequency signal 130, VCO 124 can have a wideband and hence a low Q. The VCO 124 potentially has a higher jitter generation than VCO 114, and thus a wide loop bandwidth can be utilized in the second stage 104 to reduce the jitter contribution of the VCO 124 on the PLL output signal such that the second stage 104 of the PLL performs as high pass filter to the jitter transfer function from the VCO 124 to the PLL output. The wider the loop bandwidth, the higher the cutoff frequency in the jitter transfer characteristic becomes, increasing the suppression of the low frequency VCO jitter. Because of these two requirements, namely suppressing the jitter of the potentially low cost system clock or reference source and providing a wide range of clock frequencies to the operational circuits, a cascade of two phase locked loop circuits can be beneficial. One benefit of utilizing a higher speed internal feedback loop in the second stage 104 is that the jitter contribution of the feedback divider can be significantly reduced. The contribution of the feedback divider to the PLL's jitter budget can be approximately expressed by log10(N) where N is the division ratio in the feedback path and log10 denotes the logarithm function. A higher reference frequency, utilizing a lower division ratio also reduces the latency in the feedback path and makes the control loop faster. This faster control loop can also significantly reduce the jitter and virtually eliminate the dead zone that typically occurs when the PLL is approaching a phase lock condition. Accordingly, improved control can be achieved by this improved high speed FFPFD 106, the gain controller 318 and the high speed control loop 132.

The input reference frequency 130 can have a low reference frequency and the first stage 102 can filter the reference frequency 130 utilizing a small or relatively slow loop or narrow loop bandwidth. The bandwidth of the first PLL 102 can be on the order of a few kHz. The second stage of the PLL 104 can reduce the VCO jitter by utilizing a relatively wide loop bandwidth, and utilizing a relatively high reference frequency provided by the output of the first stage PLL 102. The loop bandwidth of the second PLL 104 may range from a few tens of MHz up to about one tenth of the PLL's output frequency. It has been determined that a feedback loop with one tenth of the PLL's output frequency will ensure system stability. In accordance with the present disclosure, when the PLL output is utilized to clock serial data, the loop frequency may operate at speeds over two GHz depending on the required data rate.

As with almost all control loops, the bandwidth of the closed loop 132 is limited by the PLL's stability. In the present disclosure, the stability of the first stage 102 with respect to its input reference frequency is typically not an issue because the first stage control loop 134 has a relatively low frequency with a relatively small bandwidth. However, the second stage 104 of the cascaded PLLs has a much greater bandwidth operating at a much higher frequency. Traditional PLL theory dictates that the loop bandwidth of the PLL has to be smaller than one tenth of the reference frequency 130 or 136 to guarantee a stable operation of the stage. If the gain provided by each stage, for example by the PFD becomes too big this can cause serious instability in a PLL. One feature of the FFPFD 106 is that the FFPFD 106 can provide a phase detector gain that is twice as high as that of traditional PFDs. This is beneficial to obtain a fast locking transient when the PLL is attempting to lock. However when the PLL is in a locked state, a lower gain is desired to increase the phase margin and thus the stability of the PLL. In other words, a low loop gain in the locked state makes the PLL less prone to jitter generating non-idealities such as loop filter leakage or charge pump mismatch. The subsequently described gain analysis and control module can perform an adjustment of the overall loop gain dependent on the current locking state of the PLL.

Referring to FIG. 2, a portion of a feed-forward path of a phase locked loop (PLL) 200 is disclosed. The portion of the PLL 200 can include a phase frequency detector (PFD) 202, a charge pump 204 and loop gain analysis/control module depicted within dashed box 216. The loop gain analysis/control module 216 can consist of a delay module 206, a compare module 208 a gain analysis module 210 and a current adjustment module 212. The output of the charge pump 204 can feed, or control an oscillator 214 of the PLL via a loop filter (not shown).

The delay module 206 and the compare module 208 can acquire jitter data and provide the jitter data to the gain analysis module 210. In turn, the gain analysis module 210 can store the jitter data and provide jitter analysis based on the data to the current adjustment module 212. The current adjustment module 212 can have look up tables that can be utilized to coordinate a control configuration based on the acquired data. The loop gain analysis/control module 216 can adaptively adjust the overall loop gain of the PLL as a function of the PLL's locking state or as a function of the statistical jitter on the loop. During a period of time where the PLL is not locked, and is transitioning to a locked condition, the loop gain analysis/control module 216 can provide a high loop gain that will speed up the transient locking process and once the PLL is locked, the loop gain analysis/control module 216 can automatically reduce the loop gain to enhance steady state stability. Reducing the loop gain can make the PLL less prone to jitter generating non-idealities such as loop filter leakage which may occur when the PLL has achieved a lock. Additionally, the loop gain analysis/control module 216 can correct for possible charge pump mismatches (i.e. mismatch of PMOS and NMOS field effect transistor devices in current sources or comparators).

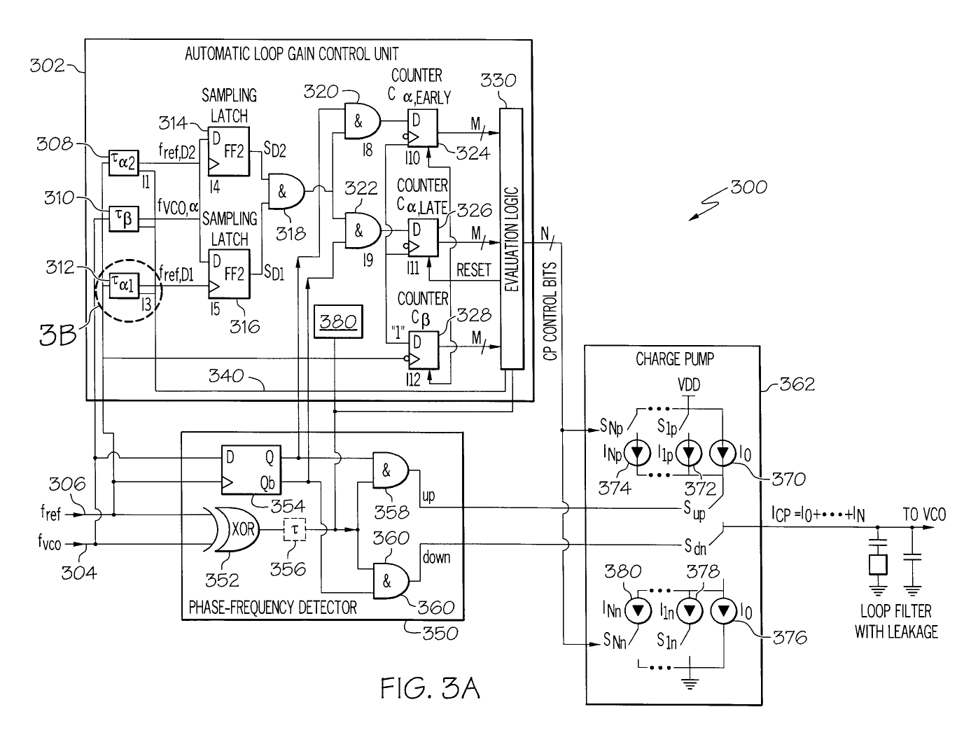

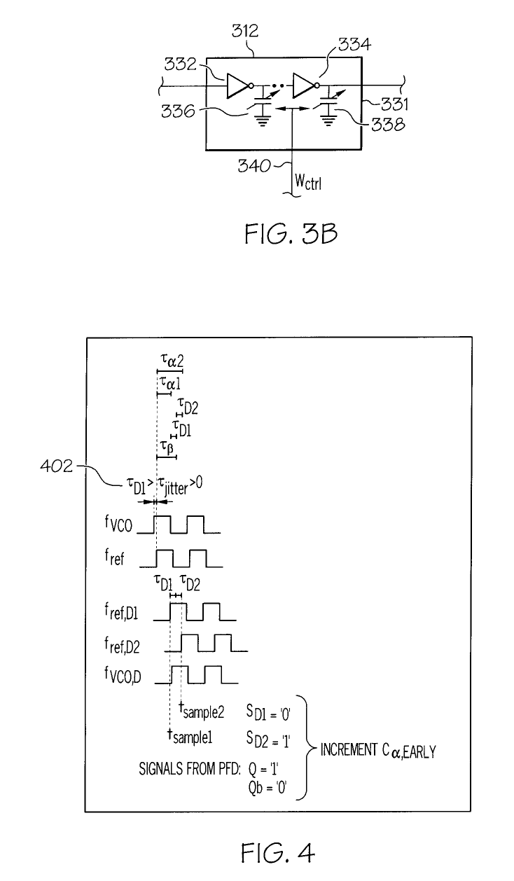

Referring to FIG. 3A, a more detailed block diagram of a portion of a PLL loop 300 is depicted. The PLL loop portion 300 can include phase frequency detector 350, loop gain analysis/control unit or module 302, and an oscillator controller such as a charge pump 362. The oscillator could take many forms such as a variable impedance/reactance module, a variable inductor, a transistor, a current to voltage conversion module, or any combination components that can be utilized to change an oscillation frequency. The loop gain control module 302 can include delay modules 308, 310 and 312, sampling latches 314 and 316, AND gates 318, 320, 322, lock detector 380, counters 324 326 and 328 and evaluation logic 330. The loop gain analysis/control module 302 can detect phase lock, detect loop filter leakage and detect charge pump mismatches and accordingly adjusted overall loop gain or provide a variable gain signal to the oscillator controller 362 such that the abnormalities mentioned above can addressed.

In operation, f_{VCO} 304 can be provided on the input of delay module 310. The delay module 310 can provide a variable delay (τ_{β}) of f_{VCO} 304 to the D inputs of sampling latches 314 and 316. The output of the delay module 310 can be labeled f_{VCO,D}. The reference frequency signal f_{ref} 306 can be split into two signal paths I1 and I3. Delay module 308 in the first signal path can delay the f_{REF} signal 306 by τ_{α2} while delay module 312 in the second signal path can delay the f_{REF} signal by τ_{α1}. The outputs of the variable delay lines 308 (I1) and 312 (I3) are referred to herein as f_{ref,D2} and f_{ref,D1}, respectively.

The gain control module 302 can determine jitter parameters on the PLL by evaluating the timing edges the f_{ref} and f_{VCO} signals 306 and 304. The actual delay values of the delays τ_{α1}, τ_{α2} and τ_{β} generally will not have a significant effect on jitter measurements. The delay modules 308, 310 and 312 can be controlled by the evaluation logic module 330 via a control line. The delays provided by delay modules 308, 310 and 312 can provide delay differences between τ_{β} and τ_{α1}, (i.e. τ_{β}−τ_{α1}) and between τ_{β} and τ_{α2}, (i.e. τ_{β}−τ_{α2}). These delays or delay differences can be varied continuously or the delays can be varied in discrete delay steps according to a routine processed internally by the evaluation logic module 330.

In one embodiment, delay τ_{β} can be a constant and delays τ_{α1} and τ_{α2} can be varied in relation to τ_{β}. Delays τ_{α1} and τ_{α2} can be varied about a range between 0 and half of the reference frequency period T_{ref}/2. Moreover, in one embodiment τ_{α2}>τ_{β}>τ_{α1} such that delay module 312 will provide the smallest delay interval, delay module 310 will provide the middle delay time and delay module 308 will provide the largest delay interval. Further, the time delay differences on signals provided to sampling latch 316 can be defined as τ_{D1}=|τ_{β}−τ_{α1}| and the time delay difference on signals provided to sampling latch 314 can be defined as τ_{D2}=|τ_{β}−τ_{α2}|. Further, the delays can be configured such that the delay differences are symmetric about τ_{β}, (i.e. τ_{D1}=τ_{D2)}).

The output of delay module 310, f_{VCO,D} can be split and fed to the D-inputs of two sampling latches 314 and 316. The signal f_{ref,D1} can be fed to the clock input of sampling latch 316 and signal f_{ref,D2} can be fed to the clock input of sampling latch 314. The delay differences τ_{D1} and τ_{D2} can be acquired by sampling latches 314 and 316 based on the delay times.

When the PLL is in a locked state or f_{ref} 306 has rising and falling edges that are synchronized with the rising and falling edges of f_{vco} 304, and assuming no, or insignificant jitter, the different settings of delay modules 308, 310 and 312 creating delay differences τ_{D1} and τ_{D2}, allows f_{VCO,D} to be sampled prior to its nominal rising edge by latch 316 and allows f_{VCO,D} to be sampled after its nominal rising edge by latch 314. As stated above, delay module 310 producing f_{vco,D} can have a delay time that is greater than the delay provided by delay module 312 and less than the delay provided by delay module 308, and the output of delay modules 308 and 312 can be utilized to clock in a binary signal (i.e. either 1 or 0) indicating where f_{vco} 304 signal transitions occur in time in relation to f_{ref 306} transitions.

The sampling points or sampling times specified by the outputs f_{ref,D1} and f_{ref,D2} of delay modules 308 and 312, define a timing interval τ_{D1}+τ_{D2} around τ_{β} where the rising edge of f_{VCO,D} may occur due to jitter, but the sample values may not indicate a case of unacceptable jitter. In other words, the waveform edges of the adjustable delay sampling clock signals f_{ref,D1} and f_{ref,D2} can define a region or time frame wherein a maximum allowable or acceptable peak-to-peak jitter of f_{VCO} can occur and such occurrences will not be recorded by the gain control module 302 as unacceptable jitter during this interval. Based on the operation of the PLL, the size of this peak-to-peak jitter timing interval can be varied by delay modules 308 and 312 creating τ_{α2} and τ_{α1} under the control of the gain control module 302.

The outputs of the sampling latches 314 and 316, referred to herein as s_{D2} and s_{D1} respectively, can be fed forward to AND gate 318. The signal at the output of latch 314 can be inverted at the input of the AND gate 318. Generally, AND gates 318, 320 and 322, the counters 324, 326, 328, and the evaluation logic 330 can process the s_{D1} and s_{D2} signals and derive jitter statistics on f_{VCO}, 304. The jitter statistics can then be utilized to adjust the loop gain of the PLL described with reference to FIG. 1.

In accordance with the present disclosure, the gain can be increased, decreased or transferred to another component of the PLL based on the detection of specific statistical ranges that indicate specific phenomena. For example, the PFD 350 can have circuitry that provides gain and when the PLL is not locked the PFD 350 can provide a high gain and then when the PLL is locked a portion of the PFD gain could be transferred to the charge pump 362 via gain control module 302. Alternately, and as disclosed above, the gain provided by the gain control module 302 and the charge pump 362 can be high when the PLL is transitioning to a phase lock, such that a lock can be quickly achieved, but then in an effort to reduce jitter on the output of the PLL during steady state operation, the gain control module 302 can decrease the gain provided by the charge pump 362 once the PLL is locked. For example, under extreme jitter considerations the charge pump gain and the overall loop gain can be set to a minimum value. However, such a minimum value would be unacceptable on start up or when the phase lock is lost by the PLL.

Thus, the evaluation logic 330 can control the charge pump 362 based on a detection of a phase lock in the PLL. In one embodiment, phase lock detector 380 can analyze the phase difference of the phase detector input signals f_{vco} 304 and f_{ref} 306 to determine if signals 304 and 306 are phase-aligned which will indicate a locked state of the PLL. In another embodiment, the lock detector 380 can determine a locked status of the PLL by monitoring the output pulse width of XOR gate 352. In a locked condition the output of the XOR gate 352 will be at a steady state or will not toggle very often. As can be appreciated, many different design configurations could be utilized to determine when the PLL is in a locked condition or alternately is not in a locked condition and these different configurations would not depart from the scope of the present disclosure.

In the PLL disclosed in FIG. 1 gain can be incorporated in and transferred to nearly any stage or component in the loop. In accordance with the present disclosure, the charge pump 362 has been chosen as a place in the PLL to adjust the overall PLL loop gain. The charge pump 362 has been chosen because, in one embodiment, it has been determined that adding gain at the charge pump stage 362 provides improved PLL control as compared to directly adjusting the gain in the VCO stage or the adjusting the gain in the PFD stage 350. The impact of the gain of the charge pump 362 on the overall loop gain is illustrated by the closed loop transfer function of the PLL below:

$$\frac{{Φ}_{out} ( s )}{{Φ}_{in} ( s )} = \frac{{K}_{PD} \cdot {K}_{CP} \cdot {K}_{VCO} \cdot F ( s )}{s + {K}_{PD} \cdot {K}_{CP} \cdot {K}_{VCO} \cdot F ( s )} , \qquad ( 1 )$$

where

F(s): transfer function of loop filter

K_{CP}: charge pump gain

K_{PD}: phase detector gain

K_{VCO}: VCO gain

The gain control module 302 can utilize signals from the PFD 350 that provide information regarding which input signal (i.e. f_{REF} 306 or f_{VCO} 304) leads or lags the other signal. PFD 350 can include a phase difference sensor embodied herein as an exclusive OR (XOR) gate 352, a lead lag sensor embodied as a D-flip-flop 354, a time delay module 356, and steering logic, embodied by two AND-gates 358 and 360.

In operation, the XOR-gate 352 can measure the phase difference between the reference signal f_{REF} 306 and the VCO signal f_{VCO} 304 and provide a phase difference duration signal on its output indicating a duration that a rising edge of f_{REF} 306 leads or lags f_{VCO} 304. The D-flip flop 354 can have two output signals, a Q output providing a logic high when f_{REF} 306 lags f_{VCO} 304, and a Qb output providing a logic high when the f_{REF} 306 leads the f_{VCO} 304. The XOR-gate 352 can produce a logic high output when f_{REF} 306 and f_{VCO} 304 have different logical levels or are at different states. A XOR-gate logic high output indicates a period of time when a phase difference exits between f_{REF} 306 and the f_{VCO} 304. The D-flip-flop 354 can sense or determine whether the rising edge of f_{VCO} 304 leads or lags the rising edge of f_{REF} 306. Thus, the D-flip-flop 354 can produce a logic high output on a Q output if f_{REF} 306 lags f_{VCO} 304 and the D-flip-flop 354 can produce a logic high output on a Qb when f_{VCO} 304 lags f_{REF} 306. The outputs of the D flip-flop 354 can then be utilized to control or activate AND-gates 320 and 322.

When the Q output of the D-flip flop 354 is high, the Qb output of the D-flip flop 354 will be low and vise-versa. Thus, the output of the XOR-gate 352 can provide a pulse representative of the time when a phase difference exists between f_{REF} 306 and f_{VCO} 304, while the D-flip flop 354 can provide a steering signal to the gain control module 302 representing whether f_{VCO} 304 leads f_{REF} 306 on a first output or a second steering signal when f_{VCO} 304 lags f_{REF} 306.

Accordingly, the signal at the output of AND-gate 320 can steer a count of when f_{REF} 306 lags f_{VCO} 304, to early counter 324 since the edge of f_{VCO} 304 occurs earlier than the edge of f_{REF} and AND gate 322 can provide an output signal when f_{REF} 306 leads f_{VCO} 304, to late counter 326 since the edge of f_{VCO} 304 occurs later than the edge of f_{REF} 306. The outputs of AND gates 358 and 360 can provide a lead or lag signal magnitude indicator to charge pump 362 indicating whether the current provided by the charge pump 362 should be increased or decreased such that the frequency of the VCO loop (f_{VCO} 304) will increase or decrease to achieve a locked condition.

As stated above, the outputs Q and Qb of the sampling latch or D-flip-flop 354, allow the AND gates 320 and 322 to steer a jitter indicative signal acquired by sampling latches 314 and 316 and AND gate 318 to an early counter 324 when the jitter is related to an early fvco 304 rising edge and steer a jitter signal to a late counter 326 when the jitter indicative signal is related to a late rising edge of f_{VCO} 304 based on the rising edge of the f_{REF} 306. If Q=1 and Qb=0, the output of the AND gate 320 connected to the D-input of the counter C_{α,early} 324 becomes logical high and the output of AND gate 322 becomes a logical zero. If Q=0 and Qb=1, the output of the AND gate 322, which is connected to the counter C_{α,late}, 326 will be a logical one ‘1’ and the output of AND gate 320 will be a logical zero ‘0.’ Both counters C_{α,early} and C_{α,late} 324 and 326 can be clocked on the falling edge of the reference signal f_{ref} 306. The falling edge of the reference signal f_{ref} 306 can be utilized to account for the delay through the sampling latches 314 and 316 and to ensure correct setup times at the input of the counters 324 and 326.

Early counter, C_{α,early} 324 can count the occurrences of a rising edge of f_{VCO} 304 in the ‘early’ interval 0<τⱼᵢₜₜₑᵣ<τ_{D1} and late counter C_{α,late} 326 can count the occurrences of a rising edge of f_{VCO} 304 in the ‘late’ interval 0<τⱼᵢₜₜₑᵣ<τ_{D2}. Third counter C_{β} 328 can be incremented every rising edge of f_{ref} 306. Counter values ValC_{α,early} of counter C_{α,early}, 324, ValC_{α,late} of counter C_{α,late} 326, and ValC_{β} of counter C_{β} 328 can be fed through M-bit wide buses to the evaluation logic module 330 that can control the gain settings of the charge pump 362 based on ValC_{α,early} and ValC_{α,late}.

A truth table representation useable by the gain control module 302 is provided in Table I below. Table I generally provides a counter update based on different delay settings where, responsive to the inputs and corresponding output(s) of the D-flip flop 354 and the AND gate 318, the early counter 324 and the late counter 326 can be incremented to acquire statistics on jitter in the PLL system.

TABLE I

| | s_{D1} | s_{D2} | Q | Qb | n& | C_{α,early} | C_{α,late} |
|---|---|---|---|---|---|---|---|
| Case A (τ_{D1} > τⱼᵢₜₜₑᵣ > 0) | 0 | 1 | 1 | 0 | 1 | increment | — |
| Case B (0 < τⱼᵢₜₜₑᵣ < τ_{D2}) | 0 | 1 | 0 | 1 | 1 | — | increment |
| Case C (τⱼᵢₜₜₑᵣ > τ_{D1)} | 1 | 1 | 1 | 0 | 1 | — | — |
| Case D (τ_{D2} < τⱼᵢₜₜₑᵣ) | 0 | 0 | 0 | 1 | 1 | — | — |
| Case E (τⱼᵢₜₜₑᵣ + τ_{D1}) > | 1 | 0 | 1 | 0 | 0 | — | — |
| T_{ref} | | | | | | | |
| Case F (τⱼᵢₜₜₑᵣ + τ_{D2}) > | 1 | 0 | 0 | 1 | 0 | — | — |
| T_{ref} | | | | | | | |

Tables II and III below are just one example of how to control the gain in the PLL based on statistical jitter. In the example provided by Tables II and III, the number of cycles that trigger an evaluation by the evaluation logic module 330 has been set to here 2⁷ or 128 cycles (referred to herein as “ValC_{β,max}”). However, this count could be altered to balance maximizing the accuracy of the acquired jitter statistics with the response time of the control corrections based on the jitter statistics, (i.e. how big of a time sample will yield accurate jitter data, versus how small of a sample time will yield inaccurate statistical data, versus an unacceptably slow response time). Alternately described, a larger sample may yield greater statistical confidence but will slow the control response time.

As mentioned above, when the cycle count, ValC_{β}, as determined by counter 328 has reached a predefined value, the counts ValC_{α,early} and ValC_{α,late} from counters 324 and 326 can be retrieved by evaluation logic module 330. In response to the counts, which can be utilized in numerous ways to provide jitter statistics about the loop signals, the evaluation logic module 330 can control the charge pump 362. In another embodiment, after a predetermined time-period of operation, a timer (similar to cycle counter 328) can send an activation signal to the evaluation logic module 330 and the evaluation logic module 330 can evaluate counter values ValC_{α,early} and ValC_{α,late} to determine or acquire jitter statistics.

As stated above, when a cycle counter is utilized and ValC_{β} has reached a predefined or predetermined value, “ValC_{β,max}” the counts provided by counters 324 and 326 (i.e. C_{α,early}, and C_{α,late}) can be evaluated by evaluation logic module 320. After the evaluation of the counter values C_{α,early}, and C_{α,late}, a corresponding update or adjustment of the gain settings can be made utilizing the information provided in Tables II and III below to adjust charge pump 362. After such adjustments, all counters (i.e. 324, 326 and 328 can be reset to zero and the process can start a new counting/evaluation session.

Look up Tables II and III can be utilized to provide the proper adjustment of loop gain by dictating how many, or alternately, which current sources 370, 372, 374, 376, 378, and 380 in the charge pump 362 are to be switched on or off. In Table II the notation I_{xp/n} refers to Iₓₚ and Iₓₙ as is provided by the notation of the current sources 370, 372, 374, 376, 378, and 380 (370-380) in the charge pump 362. As stated above, Tables II and III are merely examples of how gain and current sources can be controlled and any variations in table data would not depart from the scope of this disclosure. In addition, a varied voltage level output instead of a digital control signal for current sources could be provided as an output from the evaluation logic module 330 and such an embodiment also would not depart from the scope of the present disclosure. Table II and Table III below illustrates two possible embodiments or routines that can be utilized by the evaluation logic 320 to adjust the gain settings of the charge pump 362. In one embodiment, counters (i.e. 324, 326 and 328) are seven-bit wide counters to provide the required count.

TABLE II

| ValC_{α,early} + ValC_{α,late} | Charge pump settings adjusted by evaluation logic |
|---|---|
| [113 . . . 128] | All switchable tail current sources off (only I0 on) |
| . . . | I_{1p/n} on; others off |
| [49 . . . 72] | I_{1p/n}, I_{2p/n} on; others off |
| [25 . . . 48] | I_{1p/n}, I_{2p/n}, I_{3p/n} on; others off |
| [9 . . . 24] | . . . |
| [0 . . . 8] | I_{1p/n}, . . . I_{Np/n} on; none off |

In Table II the sum of ValC_{α,early} and ValC_{α,late} is evaluated to adjust the gain of the charge pump 362 by activating current sources 370-380. The closer this sum is to the value ValC_{β,max} (here 2⁷=128 the number of cycles that trigger an evaluation), the less the detected jitter on f_{VCO} 304 and the less the charge pump 362 needs to be adjusted. Further, it has been determined that generally, with the appropriate time delays, (i.e. τ_{D1} and τ_{D2}) the closer the sum of ValC_{α,early} and ValC_{α,late}, is to ValC_{β,max}, the lower the jitter that is being created by potential loop filter leakage. However, the sum of ValC_{α,early}+ValC_{α,late} is generally dependent on the size of time delays τ_{D1} and τ_{D2}, so for improved operation, the time delays can be adjusted accordingly. The more τ_{D1} and τ_{D2} approach τ_{β}, or the closer τ_{D1} and τ_{D2} are to τ_{β}, the smaller the peak-to-peak jitter detection interval becomes and the more probable jittered edges are occurring on f_{VCO} 304 outside of this interval and hence are going undetected. Therefore, a smaller count or value of early and late occurrences (i.e. ValC_{α,early}+ValC_{α,late}) can be expected with smaller sampling delays (τ_{α1} and τ_{α2}).

Generally, the larger the sampling delay, the larger the jitter count will become. As illustrated in Table II, a smaller value of ValC_{α,early}+ValC_{α,late}, activates more current sources in the charge pump 362, thereby increasing the overall loop gain where a larger value of ValC_{α,early}+ValC_{α,late}, activates less current sources, or de-activate more current sources in charge pump 362 thereby decreasing the overall loop gain. In Table III discloses another refinement to loop gain adjustment, wherein the loop gain adjustment can be performed based on the count difference between ValC_{α,early} and ValC_{α,late}. The difference between ValC_{α,early} and ValC_{α,late} may indicate a charge pump mismatch and the loop gain adjustment can be refined based on this determination.

TABLE III

| | ValC_{α,early} − | Charge pump settings |
|---|---|---|
| ValC_{α,early} + ValC_{α,late} | ValC_{α,late} | adjusted by evaluation logic |
| | . . . | . . . |
| [49 . . . 72] | [−8 . . . −5] | I₁ₚ on; I₂ₚ, I₃ₚ off; |
| | | I₁ₙ, I₂ₙ, I₃ₙ on; |
| [49 . . . 72] | [−4 . . . −1] | I₁ₚ, I₂ₚ on; I₃ₚ off; |
| | | I₁ₙ, I₂ₙ, I₃ₙ on; |
| [49 . . . 72] | 0 | I₁ₚₙ, I₂ₚₙ, I₃ₚₙ on; |
| [49 . . . 72] | [1 . . . 4] | I₁ₚ, I₂ₚ, I₃ₚ on; |
| | | I₁ₙ, I₂ₙ on; I₃ₙ off; |
| [49 . . . 72] | [5 . . . 8] | I₁ₚ, I₂ₚ, I₃ₚ on; |
| | | I₁ₙ on; I₂ₙ, I₃ₙ off; |
| | . . . | . . . |

Table III illustrates when there is a count difference, there is a potential ‘early’ or ‘late’ overhang in the edge statistics of f_{VCO} 304. It has been determined that such a count might be an indication of a potential charge pump mismatch in the PLL where the current provided by individual current modules (i.e. 370-374) does not match the current provided by a corresponding current sink (i.e. 376-380). This mismatch phenomenon often occurs because of uncontrollable manufacturing tolerances and fabrication variations. Typically referred to as an N/P mismatch, this phenomenon occurs when N type metallic oxide semiconductor field effect transistors (MOSFET) devices and P type MOSFET are manufactured by different processes on the same wafer. As illustrated in Table III, the count difference can be utilized to asymmetrically turn on, or off, additional current sources/sinks in the charge pump 362 such that a match can be achieved in the charge pump 362. For example, in accordance with one embodiment, if the sum of ValC_{α,early}+ValC_{α,late} is within the range of [49 . . . 72], and the difference ValC_{α,early}−ValC_{α,late} is between −4 and −1, then three additional n-type current sources will be turned on but only two additional p-type current sources will be turned on such that the biasing currents will match.

Generally, the sampling clocks define an interval of maximum allowable peak-to-peak jitter of f_{VCO} caused by a charge pump mismatch such that it can be determined whether the rising edges of f_{VCO,D} are occurring within the specified maximum peak-to-peak jitter interval. This negative difference value indicates a potential charge pump mismatch, and matching can be accomplished via selective activation of current sources 370-374 (p-type) and current sinks 376-380 (n-types) referred to collectively as current modules 370-380. As can be appreciated, jitter on f_{VCO} 304 can occur at many different times in relation to the delays τ_{α1} and τ_{α2}.

Referring to FIG. 3B, an exemplary embodiment of the delay module 312 of FIG. 3A has been illustrated as a “blow-up” window. The illustrated embodiment of 312 can also be implemented by delay modules 308 and 310 in FIG. 3A. The delay modules can be implemented as a cascade of inverter stages that, when properly controlled, can provide variable delays of their input signal on their output. Inverters 332 and 334 with variable capacitive loads 336 and 338 illustrate one way to implement delay modules. Although only two stages or two inverters are illustrated, any number of delay inverters each having various delay times could be utilized to provides the desired delay to the system. In one embodiment, the load capacitances 336 and 338 can be digitally adjusted by the evaluation logic module 330 via a control word W_{ctrl} as indicated by the control line 340.

FIGS. 4-9 depict at least some possible timing combinations and the logic value output provided to the counters based on time relationships when the jitter occurs.

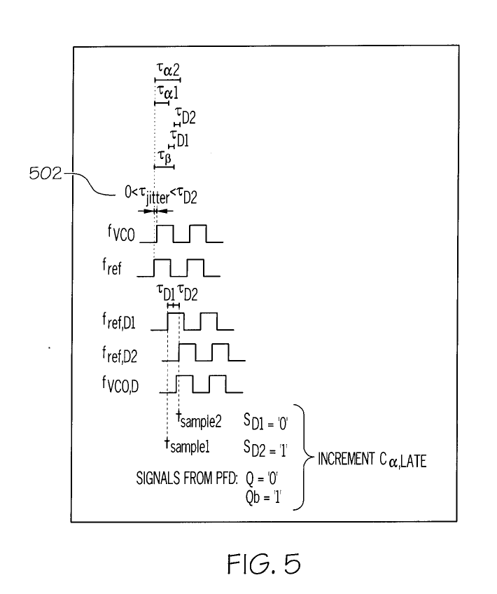

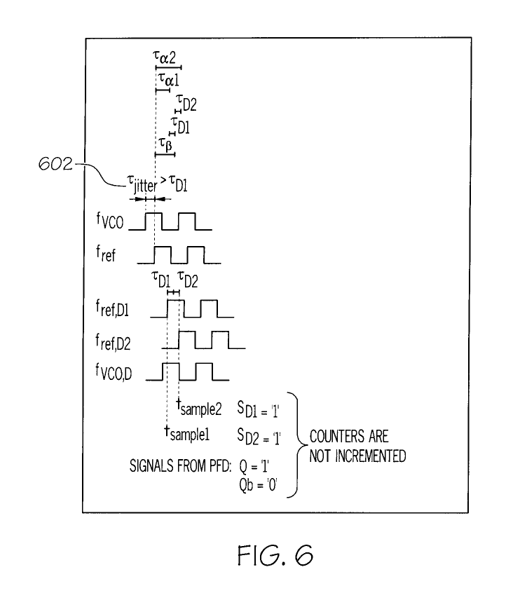

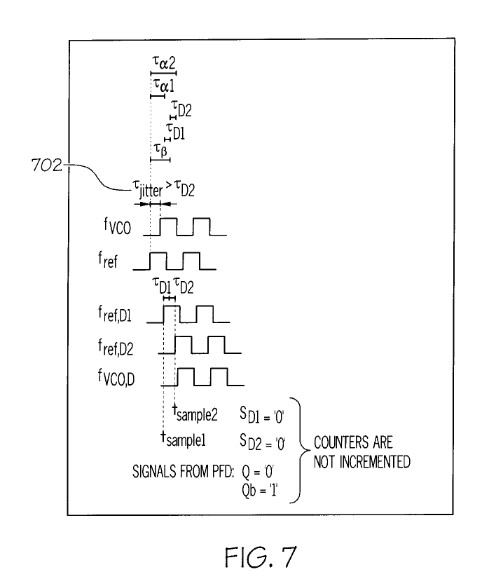

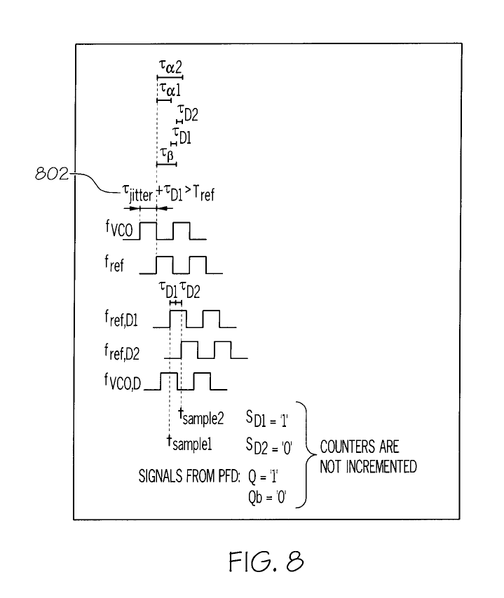

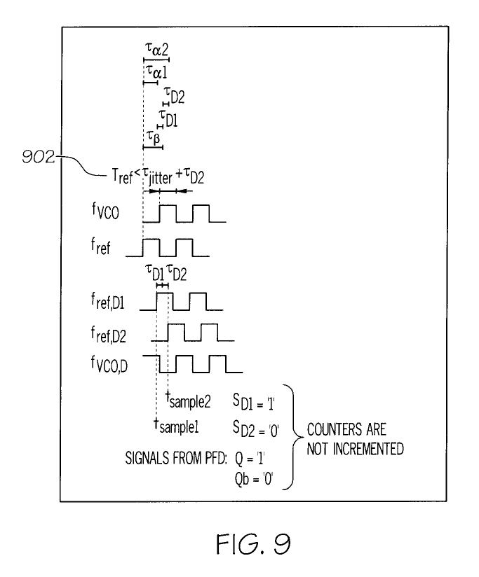

FIG. 4 illustrates that case where the amount of jitter is bounded by 0<τⱼᵢₜₜₑᵣ<τ_{D1}, (402) FIG. 5 illustrates the case where the amount of jitter is bounded by 0<τⱼᵢₜₜₑᵣ<τ_{D2}, (502), FIG. 6 illustrates the case where τⱼᵢₜₜₑᵣ>τ_{D1}, (602), FIG. 7 illustrates the case where τⱼᵢₜₜₑᵣ>τ_{D2}, (702), FIG. 8 illustrates the case where τⱼᵢₜₜₑᵣ+τ_{D1}>T_{ref} (802) and FIG. 9, illustrates the case where τⱼᵢₜₜₑᵣ+τ_{D2}<T_{ref} (902). Further, FIGS. 4-7 illustrate different signal constellations with τⱼᵢₜₜₑᵣ+τ_{D1/D2}<T_{ref} and FIGS. 8 and 9 illustrate different signal constellations with τⱼᵢₜₜₑᵣ+τ_{D1/D2}>T_{ref}: Important timing constellations between f_{ref} 306 and f_{VCO} 304 are illustrated in FIGS. 4-9 where the timing relationship of f_{ref} 306 with respect to f_{VCO} 304 is illustrated in each FIG. 4-9 just below the timing of the jitter (i.e. 402, 502, 602, 702, 802, and 902). In FIGS. 4 and 5 (0<τⱼᵢₜₜₑᵣ<τ_{D1} and 0<τⱼᵢₜₜₑᵣ<τ_{D2}), and the following samples s_{D1}=0 and s_{D2}=1 are obtained by the sampling latches.

To distinguish between 0<τⱼᵢₜₜₑᵣ<τ_{D1} (early case) and 0<τⱼᵢₜₜₑᵣ<τ_{D2} (late case), the output signals Q and Qb of the D flip-flop of the PFD are fed to steering logic (i.e. AND gates) of the gain control unit. The early case (0<τⱼᵢₜₜₑᵣ<τ_{D1}) provides PFD output signals of Q=1 and Qb=0 and the late case (0<τⱼᵢₜₜₑᵣ<τ_{D2}) provides PFD output signals of Q=0 and Qb=1. As described with respect to FIG. 3A, the sampling latch outputs s_{D1} and s_{D2} are fed to a 2-input AND gate 318 (I6) whose output is fed to two AND gates 320, 322 (I8, I9) that steer the count from sampling latches to either the early counter or the late counter.

For the cases where (0<τⱼᵢₜₜₑᵣ<τ_{D1,2} with τⱼᵢₜₜₑᵣ+τ_{D1,2}<T_{ref}) as in FIGS. 4 and 5 it can be appreciated that the output of AND gate 318 (I6) is always logical high. The above analysis has assumed that τⱼᵢₜₜₑᵣ<τ_{D1/2} and τⱼᵢₜₜₑᵣ+τ_{D1,2}<T_{ref}. However, if a high value of τⱼᵢₜₜₑᵣ is present on f_{vco} 304 this assumption may not be valid. Note that the condition τⱼᵢₜₜₑᵣ+τ_{D1,2}<T_{ref} may also be violated by a high value of τ_{D1/2}. It can be appreciated that, one feature of the loop gain control unit 302 is to automatically monitor and correct potential loop filter leakage or charge pump mismatch during a locked state of the PLL. As stated above, the logic module can set τ_{D1/2} based on the results of the jitter data. It can be appreciated that τ_{D1/2} should not be set such that is has a magnitude close to T_{ref}. It has been determined that setting T_{D1/2} to be a small fraction of T_{ref} can provide the desired performance, where it can be assumed that the condition τⱼᵢₜₜₑᵣ+τ_{D1,2}<T_{ref} is primarily violated by a high value of τⱼᵢₜₜₑᵣ—and not by an inappropriate choice of τ_{D1,D2}.

In FIG. 6, a case is illustrated that may occur if τⱼᵢₜₜₑᵣ is higher than the predefined peak-to-peak jitter interval τ_{D1}. If τⱼᵢₜₜₑᵣ>τ_{D1} and τⱼᵢₜₜₑᵣ+τ_{D1}<T_{ref}, and therefore the outputs of the sampling latches can be s_{D1}=1 and s_{D2}=1. In FIG. 7, the condition τⱼᵢₜₜₑᵣ>τ_{D2} and τⱼᵢₜₜₑᵣ+τ_{D2}<T_{ref} is illustrated where the outputs of the sampling latches become s_{D1}=0 and s_{D2}=0. The case where τⱼᵢₜₜₑᵣ is as high as T_{ref}<τⱼᵢₜₜₑᵣ+τ_{D1/2}<2*T_{ref} will change the output of the sampling latches to s_{D1}=1 and s_{D2}=0 as illustrated by FIGS. 8 and 9. Generally, FIG. 8 illustrates an early configuration and FIG. 9 illustrates a late configuration where the counters are not incremented because the output of the AND gate 318 (I6) remains at logical zero since s_{D1}=1 and s_{D2}=0.

It can be appreciated in all cases represented by FIGS. 6-9 that counters C_{α,early} or C_{α,late} are not incremented because jitter is not detected in the predetermined peak-to-peak interval, however, the cycle count C_{β} is always incremented by f_{ref} cycles. In FIGS. 6-9 C_{α,early} and C_{α,late} are not incremented because AND-gate 318 (I6) has one inverted input and the output of that AND gate is only logical one if s_{D1}=0 and s_{D2}=1, which corresponds to the case where τⱼᵢₜₜₑᵣ is within the predefined peak-to-peak jitter interval as in FIGS. 4 and 5. In all other combinations of s_{D1} and s_{D2}, (namely those combinations where the τⱼᵢₜₜₑᵣ is bigger than τ_{D1} or τ_{D2}) the output of the AND gate 318 is zero and hence the output of the AND gates 320 (I8) and 322 (I9) are zero as well, which prevents the counters C_{α,early} 324 and C_{α,late} 326 from incrementing.

AND gate (318 in FIG. 3A) has an inverted input, thus when τⱼᵢₜₜₑᵣ+τ_{D1/2}>T_{ref}, the output of the sampling latches will have different values. This condition can turn on AND gate 318 such that AND gate 318 provides a logical one “1” on its output. However, if the jitter is very high so that τⱼᵢₜₜₑᵣ+τ_{D1/2}>2*T_{ref}, then the illustrated logic levels of FIGS. 4 and 5 will apply again and this can lead to a false jitter detection. In such a case, the PLL generally suffers from a cycle slip and the PLL will typically loose its lock when this occurs. The gain control module can be configured to receive an input indicating that the PLL is out of lock, and then the jitter analysis or jitter data can be ignored. In one embodiment, such an undesired false detection case can be detected by a cycle slip or the lock detector and such detection can prevent the counter C_{α,early} 324 and C_{α,late} 326 from being wrongly incremented. Lock detectors can be implemented in many different ways and such an implementation would not depart from the scope of the present disclosure.

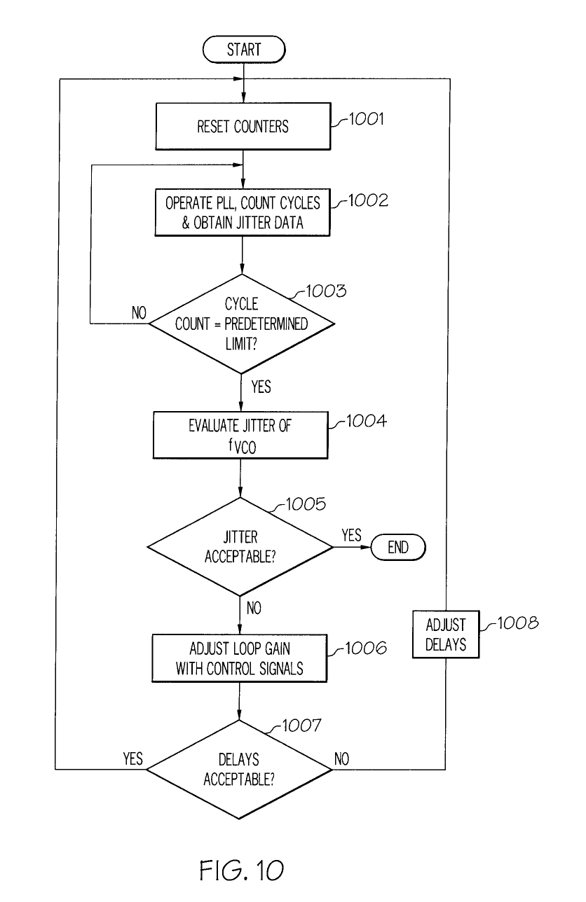

A flow diagram illustrating the functional principle of the loop gain control is shown in FIG. 10. As illustrated by bock 1001, all counters in the system can be reset. Then clock cycles of f_{VCO} can be counted by a counter, and jitter data can be acquired as illustrated by block 1002. At decision block 1003, it can be determined if the clock cycle count has reached a predetermined value or number. If the cycle count has not reached the predetermined number then the process can revert back to block 1002 where counting can continue. When the cycle count has reached the predetermined value then the obtained jitter data can be evaluated as illustrated by block 1004. Jitter evaluation can include counting cycles where jitter does not occur and during specific intervals comparing the counted jitter to the number of cycles.

At decision block 1005 it can be determined if the jitter is acceptable and if the amount of jitter is acceptable then the process can end. If it is determined that the jitter is unacceptable then the loop gain can be adjusted according to the tables above as illustrated by block 1006. Is should be noted that the charge pump gain can be adaptively adjusted to compensate for detected loop filter leakage and for detected charge pump mismatches.

At decision block 1007 it can be determined if the delays that are utilized in acquiring the jitter data are acceptable and if they are then the process can revert to block 1001 and if they are not the process can adjust the delays as illustrated by block 1008. After the delays are adjusted then the process can revert to block 1001.

Each process disclosed herein can be implemented with a software program. The software programs described herein may be operated on any type of computer, such as personal computer, server, etc. Any programs may be contained on a variety of signal-bearing media. Illustrative signal-bearing media include, but are not limited to: (i) information permanently stored on non-writable storage media (e.g., read-only memory devices within a computer such as CD-ROM disks readable by a CD-ROM drive); (ii) alterable information stored on writable storage media (e.g., floppy disks within a diskette drive or hard-disk drive); and (iii) information conveyed to a computer by a communications medium, such as through a computer or telephone network, including wireless communications. The latter embodiment specifically includes information downloaded from the Internet, intranet or other networks. Such signal-bearing media, when carrying computer-readable instructions that direct the functions of the present invention, represent embodiments of the present disclosure.

The disclosed embodiments can take the form of an entirely hardware embodiment, an entirely software embodiment or an embodiment containing both hardware and software elements. In a preferred embodiment, the invention is implemented in software, which includes but is not limited to firmware, resident software, microcode, etc. Furthermore, the invention can take the form of a computer program product accessible from a computer-usable or computer-readable medium providing program code for use by or in connection with a computer or any instruction execution system. For the purposes of this description, a computer-usable or computer readable medium can be any apparatus that can contain, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk-read only memory (CD-ROM), compact disk-read/write (CD-R/W) and DVD. A data processing system suitable for storing and/or executing program code can include at least one processor, logic, or a state machine coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modem and Ethernet cards are just a few of the currently available types of network adapters.

It will be apparent to those skilled in the art having the benefit of this disclosure that the present invention contemplates methods, systems, and media that provide a gain controller for phase locked loops. It is understood that the form of the invention shown and described in the detailed description and the drawings are to be taken merely as examples. It is intended that the following claims be interpreted broadly to embrace all the variations of the example embodiments disclosed.

What is claimed is:

1. A method of controlling a phase locked loop comprising:
receiving a reference signal and a phase locked loop feedback signal, and acquiring properties of the phase locked loop feedback signal to create acquired properties;
generating an up-down control signal based on the acquired properties;
controlling a gain based on the acquired properties with a gain control signal, the gain control signal separate from the up-down control signal;
feeding the control signal to a first input of an oscillator controller; and
feeding the gain signal to a second input of the oscillator controller.

2. The method of claim 1, further comprising:
applying a first gain control signal having a predetermined amount of gain to the oscillator controller in response to determining that the phase locked loop is out of lock; and,
applying a second gain control signal having a predetermined amount of gain to the oscillator controller in response to determining that the phase locked loop is locked.

3. The method of claim 1, wherein the gain is selectively reduced when the acquired properties indicate a phase lock.

4. The method of claim 1, wherein the gain is selectively reduced when the acquired propertied indicate jitter from a voltage controlled oscillator.

5. The method of claim 1, wherein current modules are controlled when the acquired properties indicate that there is a charge pump mismatch.

6. The method of claim 1, wherein acquiring properties comprises determining statistics on jitter of the phased locked loop feedback signal.

7. The method of claim 6, further comprising delaying the phase locked loop feedback signal and delaying the reference signal to define an interval of maximum allowable peak-to-peak jitter of the phase locked loop feedback signal and checking whether the rising edge of the delayed phase locked loop feedback signal occurs within the interval of maximum peak-to-peak jitter.

8. The method of claim 6, wherein acquiring statistics comprises counting occurrences of early jitter, counting occurrences of late jitter and counting cycles.

9. The method of claim 6, wherein acquiring statistics comprises counting cycles and evaluating the early jitter and the late jitter in response to a predetermined number of counted cycles.

10. The method of claim 6, further comprising adjusting a timing of the delayed phase locked loop signal and the delayed reference signal.

11. A gain control apparatus comprising:
a first delay module to provide a first delay of a reference signal;
a second delay module to provide a larger delay than the first delay to a loop feedback signal;
a counter to count occurrences of an edge of the delayed reference signal occurring at a different time than an edge of the delayed loop feedback signal; and
an evaluation logic module to evaluate the count occurrences and to provide a gain control output in response to the evaluated count.

12. The apparatus of claim 11, further comprising a cycle counter to count cycles and to activate the evaluation logic module when the counter cycles are at a predetermined value.

13. The apparatus of claim 11, further comprising a third delay module to provide a second delayed reference signal that is delayed more than the loop feedback signal, wherein a comparison of the second delayed reference signal to the delayed feedback signal is utilized to detect a late feedback signal.

14. The apparatus of claim 13, further comprising a second counter wherein the first counter counts early occurrences of the first delayed reference signal and the second counter counts late occurrences of the second delayed reference signal.

15. A phase locked loop system comprising:
a phase frequency detector to receive a reference signal and a loop feedback signal, and to provide one of an increase or a decrease output signal useable by an oscillator;
a gain control module to receive the reference signal and the loop feedback signal and to acquire data related to the loop feedback signal and the reference signal and provide an output signal to control a gain responsive to the data; and
a charge pump with an adjustable gain to receive the output of the gain control module and to provide an output based on the output signal of the gain control unit.

16. The system of claim 15, further comprising an oscillator to receive the output of the charge pump and to change in oscillation frequency responsive to the output of the charge pump.

17. The system of claim 15, wherein the gain control module comprises a counter to acquire data regarding occurrences of jitter.

18. The system of claim 15, wherein the reference signal is generated by a first stage phase locked loop.

19. The system of claim 15, further comprising a switch to switch gain from the phase frequency detector to the charge pump when the phase locked loop is locked.

20. The method of claim 15, further comprising operating the reference frequency at a frequency above 1.5 Gigahertz.
